(19) United States
(12) Patent Application Publication
(10) Pub. No.: US 2004/0025790 A1
(43) Pub. Date: Feb. 12, 2004

(54) Apparatus for supplying cooling gas in semiconductor device manufacturing equipment

(76) Inventor: Tai-Joon Ben, Osan-City (KR)

Correspondence Address: VOLENTINE FRANCOS, P.L.L.C., Suite 150, 12200 Sunrise Valley Drive, Reston, VA, 20191, US

(21) Appl. No.: 10/360,644

(22) Filed: Feb. 10, 2003

(30) Foreign Application Priority Data
Aug. 6, 2002 (KR) 2002-46295

(51) Int. Cl. C23C 16/00

(52) U.S. Cl. 118/724; 118/728; 156/345.53

(57) ABSTRACT

Apparatus for supplying cooling gas in semiconductor device manufacturing equipment prevents a wafer from being processed when the cooling gas supply line becomes clogged with plasma or the like. A final valve controls the supplying of the cooling gas through the line towards the back of the wafer positioned on an electrostatic chuck inside a process chamber. When the final valve is closed, cooling gas in the line is exhausted through a dump valve. The cooling gas supply apparatus is configured so that the dump valve closes either completely or to a significant extent before the final valve begins to open. Therefore, the cooling gas will not flow through the dump valve at the time the final valve opens even if the cooling gas in the line between the final valve and the process chamber is clogged with plasma.

### BACKGROUND OF THE INVENTION

1. Field of the Invention

The present invention relates to the manufacturing of semiconductor devices. More particularly, the present invention relates to an apparatus for supplying cooling gas in semiconductor manufacturing equipment.

2. Description of the Related Art

In general, the manufacturing of semiconductor devices includes an etching process in which a metal layer is first formed on a wafer and then parts of the metal layer are etched away to form a wiring pattern. In the etching process, a wafer having a photoresist pattern that exposes selected portions of the metal layer is positioned on a cathode in a processing chamber, reactive gas is introduced into the processing chamber, and the reactive gas is dissociated by power applied to the cathode and an anode to form plasma. The radicals contained in the plasma impinge the wafer and vaporize the portions of the metal layer exposed by the photoresist pattern to thereby etch the metal layer.

During this process, the temperature of the wafer becomes extremely high due to the plasma, which increase in temperature causes the photoresist deposited on the surface of wafer to bum. Such burning results in the etching of even the non-exposed portions of the metal layer and the production of a large quantity of burnt particles of the photoresist. In order to avoid such problems, helium gas is supplied onto a surface of the wafer so as to always maintain the wafer at a relatively cool constant temperature.

FIG. 1 shows typical etching equipment having such cooling means. The etching equipment includes a chamber 1, an electrostatic chuck 2 disposed in the chamber 1 for fixing a wafer W by an electrostatic force, a cooling gas feed-through 3, a filter 4, a final valve 5 and a dump valve 6.

An upper portion of the electrostatic chuck 2 has a passage into which cooling gas, such as helium (He), flows. A cooling gas line for feeding the cooling gas to the wafers W positioned on the electrostatic chuck 2 extends from this passage to the lower part of the chamber 1. The helium feed-through 3 is made of dielectric material and is configured to prevent an excessive amount of plasma from flowing inversely from the chamber 1. The filter 4 is disposed at the bottom of the helium feed-through 3. The supplying of cooling gas to the filter 4 is controlled by the final valve 5.

The cooling gas supplied through the final valve 5 opens the dump valve 6 at a point in time when the etching process is completed or is to assume a standby state. In this case, the cooling gas is exhausted through the dump valve 6 and is thereby re-supplied into the chamber 1. The cooling gas is then pumped out of the chamber 1 and exhausted together with residual gas when the interior of the chamber 1 is purged.

At present, the final valve 5 and the dump valve 6 are connected through one air line with each other and are simultaneously operated by air pressure. The final valve 5 is a normally closed valve and the dump valve 6 is a normally open valve.

FIG. 2 shows another part of the apparatus for supplying cooling gas into the processing chamber 1. This part of the apparatus comprises a shut-off valve 7, a filter 8, a flow controller 9, a valve 10, a pressure gauge 11, a bypass line 12, and a vacuum pump 13. The He gas is supplied to the final valve 5 through the shut-off valve 7, the filter 8, the flow controller 9, the valve 10 and the pressure gauge 11. When the final valve 5 is closed, the helium gas is exhausted through the bypass line 12. The bypass line 12 is connected directly to a discharge line through which reactive gas is exhausted from the chamber 1. The cooling gas in the bypass line 12 and the reactive gas is exhausted by the vacuum pump 13 under a given pressure.

The above-described conventional cooling gas supply apparatus supplies the cooling gas into the processing chamber at a constant pressure and amount, as controlled by the operation of the final valve 5. However, a minute amount of the cooling gas leaks from between the wafer W and the electrostatic chuck 2 inside the chamber 1. A process error is realized when the quantity of the leak exceeds a predetermined value, in which case the process is stopped.

Process errors, namely those conditions which when left unchecked would give rise to inferior properties in the wafers W, are accounted for by checking the amount of helium gas leaking into the chamber 1. To this end, the flow of helium is monitored at the moment the final valve 5 is opened. That is, when the final valve 5 is opened at the initiation of the plasma etching process, the flow of the helium is rapidly increased and is subsequently normalized as shown in FIG. 3. The spike in the rate of flow of helium through the apparatus at the moment the final valve 5 is opened, e.g., of about 5 sccm as shown in the figure, is referred to as the helium spike interlock value. The cooling gas supply apparatus is determined to be operating normally when the helium spike interlock value exceeds a predetermined value.

At present, however, the moment the final valve 5 is opened, the helium spike interlock value is determined by a controller to exceed the predetermined control value even when the helium feed-through 3 or the filter 4 is clogged with plasma and the cooling gas is not being supplied to the chamber 1 through the open final valve 5. As a result, the equipment is operated under a state in which the helium does not actually flow into the chamber 1. This may cause a serious process error such as the burning of the photoresist patterns on the wafers.

Such a problem occurs because the final valve 5 and the dump valve 6 are coupled with each other through the same air line, and because the operation of the final valve 5 and the dump valve 6, i.e., the opening of the final valve 5 and closing of the dump valve 6 by air pressure, occurs at the same point in time. If, at that time, the helium feed-through 3 or the filter 4 is already clogged with plasma, the cooling gas flows through the dump valve 6 until the dump valve 6 is completely closed. Consequently, the controller regards this momentary flow of the cooling gas through the dump valve 6 as the helium spike interlock value, and mistakenly determines that the helium spike interlock value exceeds the predetermined value. That is, the controller recognizes an abnormal state of operation of the cooling gas supply apparatus as a normal state of operation.

### SUMMARY OF THE INVENTION

Therefore, an object of the present invention is to provide apparatus for supplying cooling gas in semiconductor device manufacturing equipment, which will indicate the existence of a process error when a cooling gas line between a final valve and the process chamber is plugged up.

Another object of the present invention is to provide apparatus for supplying cooling gas in semiconductor device manufacturing equipment, which is capable of preventing a photoresist on a wafer from being burnt during the processing of the wafer.

To achieve these objects, the present invention provides apparatus for supplying cooling gas in semiconductor device manufacturing equipment wherein the dump valve is closed before the final valve is opened.

In the semiconductor device manufacturing equipment, cooling gas is supplied towards the back of a wafer positioned on an electrostatic chuck inside the process chamber through a final valve so as to prevent the wafer from being overheated. When the final valve is closed, the cooling gas in that portion of the supply line between the final valve and the chamber is exhausted through the dump valve.

A helium feed-through that is made of a dielectric material is disposed in the cooling gas supply line to prevent an inflow of plasma into the final valve, i.e., to prevent an inverse flow of the plasma from the chamber. The cooling gas supply line is also equipped with a filter for filtering the cooling gas upstream of the helium feed-through. A cooling gas discharge line branches from the cooling gas supply line between the final valve and the filter. The cooling gas discharge line is interlocked with the final valve by fluid pressure, and is provided with the dump valve for controlling a discharge of the cooling gas.

The final valve is a normally closed fluid-operable valve, and the dump valve is a normally open fluid-operable valve. A pair of solenoid valves is connected to a main fluid supply pipe so as to constitute branches from the main fluid supply pipe, respectively. A pair of separate fluid supply lines disposed in parallel is connected to the main pipe via the solenoid valves, respectively, such that the solenoid valves control the supplying of fluid through the respective air lines. One of the fluid supply lines extends from a respective one of the solenoid valves to the final valve, whereas the other of said fluid supply lines extends from the other of the solenoid valves to the dump valve.

The fluid supply line connected to the final valve may be longer than the fluid supply line connected to the dump valve so that the final valve will begin to open after the point in time that the dump valve has begun to close when the solenoid valves are actuated simultaneously. Alternatively, an air flow delaying unit may be disposed in the fluid supply line connected to the final valve to delay a flow of the fluid through the line. As another alternative, a signal delay device may be operatively connected to or form an integral part of the solenoid valve to which the fluid supply line extending to the final valve is connected, so as to delay the flow of current to the solenoid-actuated valve. According to any of these means, the dump valve is already either mostly or entirely closed the moment the final valve is opened. Hence, the cooling gas supplied through the final valve is supplied only to the chamber so that an accurate helium spike interlock value can be ascertained.

### BRIEF DESCRIPTION OF THE DRAWINGS

The above and other objects and features of the present invention will become apparent from the following description of the preferred embodiments thereof made in conjunction with the accompanying drawings, of which:

FIG. 1 is a side view of a conventional plasma etching equipment;

FIG. 2 is a schematic diagram of a cooling gas supply apparatus of the conventional etching equipment;

FIG. 3 is a graph showing the flowing rate of cooling gas in the conventional cooling gas supply apparatus at the time a final valve is opened;

FIG. 4 is a schematic diagram of an essential part of a first embodiment of cooling gas supply apparatus according to the present invention;

FIG. 5 is a schematic diagram of an essential part of a second embodiment of cooling gas supply apparatus according to the present invention; and

FIG. 6 is a schematic diagram of an essential part of a third embodiment of cooling gas supply apparatus according to the present invention.

### DETAILED DESCRIPTION OF THE PREFERRED EMBODIMENTS

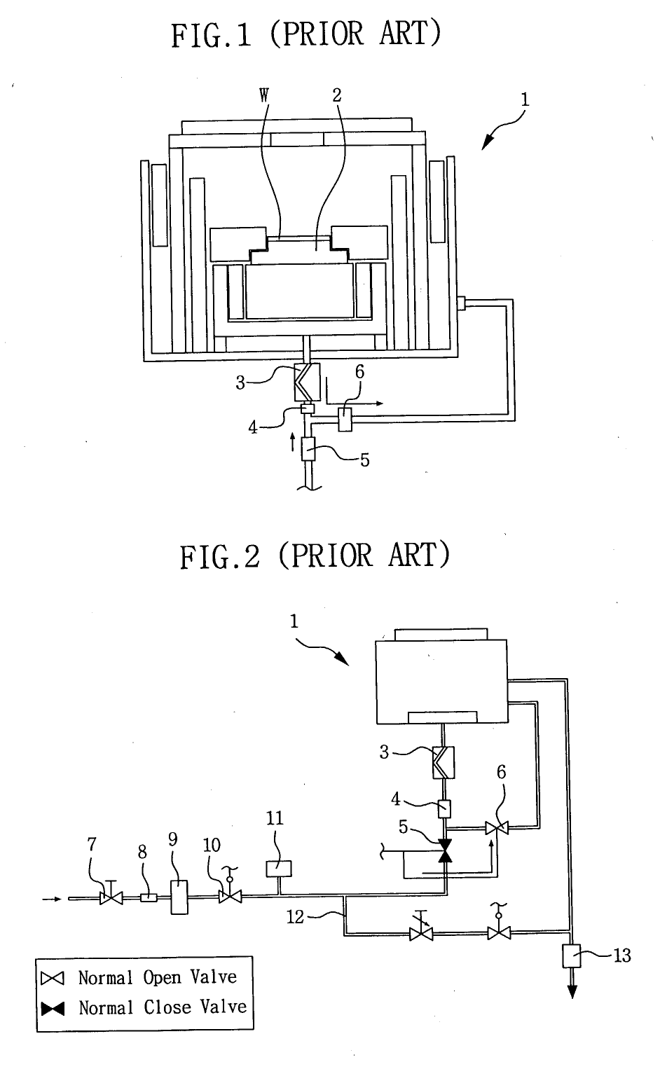

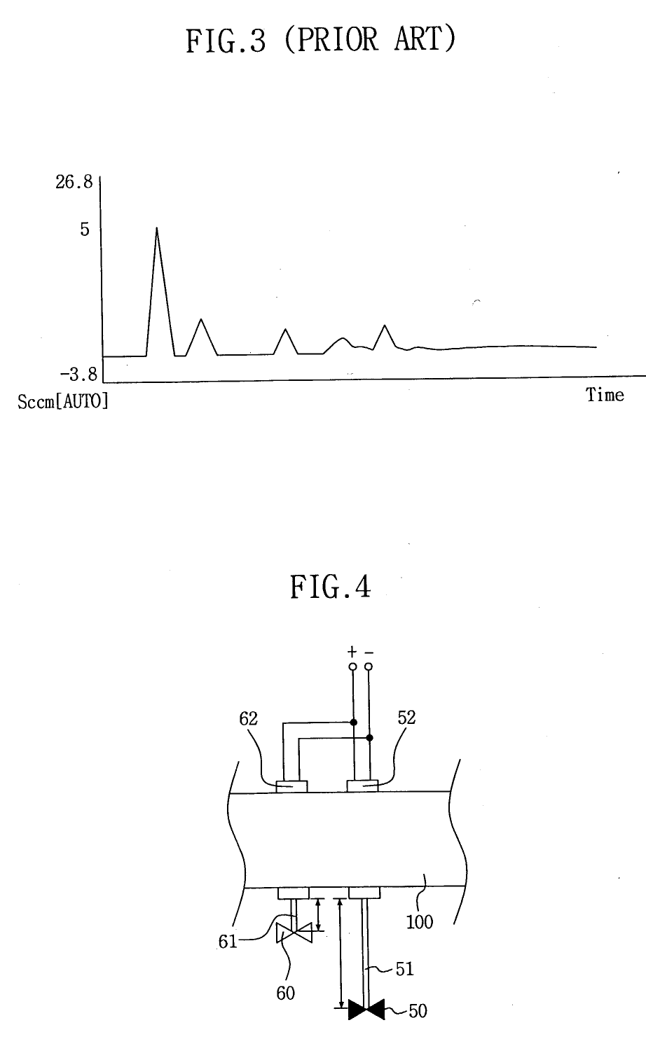

Hereinafter, preferred embodiments of the present invention will be described in detail with reference to FIGS. 4-6. The main components of the present invention are the same as those described with respect to the semiconductor manufacturing equipment of FIGS. 1 and 2 and therefore, a detailed description thereof will be omitted for the sake of brevity.

Referring first to FIG. 4, the apparatus for supplying cooling gas in the semiconductor manufacturing equipment includes a final valve 50, a dump valve 60, air lines 51, 61, a main pipe 100, and solenoid valves 52, 62. In this embodiment, the final valve 50 and the dump valve 60 are disposed in parallel in separate air lines 51, 61, respectively. That is, each of the air lines 51, 61 branch at different points from a main air supply pipe 100. Solenoid valves 52, 62 for controlling the supply of air from the main pipe 100 to the final valve 50 and to the dump valve 60, respectively, are provided at the ends of the air lines 51, 61 where the lines are connected to the main pipe 100. Thus, the air lines 51, 61 are respectively connected between the final valve 50 and the solenoid valve 52, and between the dump valve 60 and the solenoid valve 62. A characterizing feature of the first embodiment of the present invention is that lengths of the air lines 51, 61 are different from each other.

More specifically, the air line 51 connecting the final valve 50 to the main pipe 100 is longer than the air line 61 connecting the dump valve 60 to the same main pipe 100. The solenoid valves 52, 62 control the supplying of air to each of the air lines 51, 61. Power is supplied to the pair of solenoid valves 52, 62 to drive the solenoid valves 52, 62 at the same time.

In the conventional cooling gas supply apparatus, the final valve and the dump valve are operated by only one solenoid valve so as to be moved at the same time. On the other hand, in the present invention, the final valve 50 and the dump valve 60 are operated (opened and closed) at different points in time, even though the solenoid valves 52, 62 are actuated at the same time, because the air lines 51, 61 have different lengths. In particular, the dump valve 60 is driven earlier than the final valve 50 because the air line 61 is shorter than the air line 51.

Accordingly, when pressurized air is flowing through the main pipe 100 and the solenoid valves 52, 62 are simultaneously actuated so as to open the lines 51, 61 at the same time, the air flows through the lines 51, 61. This flow of air closes the dump valve 60 first and then opens the final valve 50. When the dump valve 60 is closed before the final valve 50 is opened, the moment the final valve 50 is opened, helium gas supplied through the final valve 50 will not flow any more if the helium feed-through or the filter provided downstream of the final valve 50 is plugged up. In this case, helium spike interlock value is seen as 0 sccm. The controller thus determines that the helium spike interlock is smaller than the predetermined control value and as such, stops the manufacturing process.

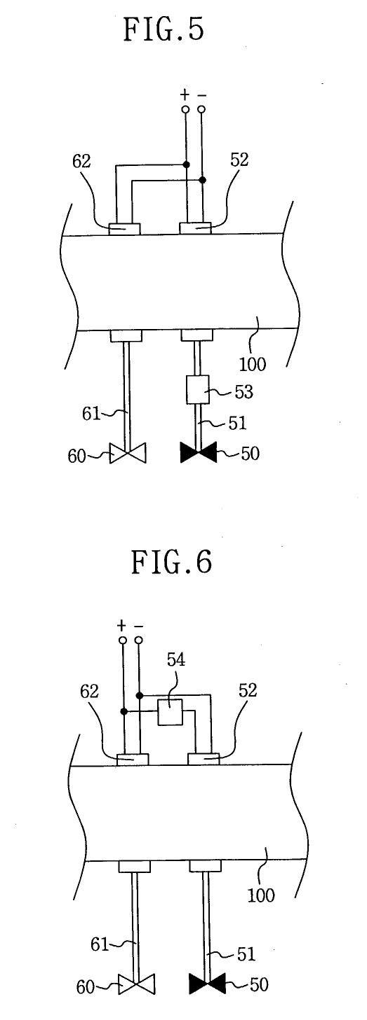

FIG. 5 shows a second embodiment of the present invention. Like the first embodiment, the cooling gas supply apparatus of the second embodiment has a final valve 50 and a dump valve 60 disposed in parallel in separate air lines 51, 61. Also, solenoid valves 52, 62 for controlling the supply of air from the main pipe 100 to the final valve 50 and to the dump valve 60, respectively, are provided at the ends of the air lines 51, 61 where the lines are connected to the main pipe 100.

In the second embodiment, however, an air flow delaying unit 53 is provided in the air line 51 connecting the final valve 50 to the main pipe 100. The air flow delaying unit 53 delays the flow of air through the air line 51 to the final valve 50. Thus, when air is supplied to the air lines 51, 61 simultaneously through the actuation of the solenoid valves 52, 62, the final valve 50 is opened after the dump valve 60 is closed due to the function of the air flow delaying unit 53 disposed in the air line 51. The air flow delaying unit 53 may alternatively control the amount of air that is capable of flowing therethrough and thus create a delay in the opening of the final valve 50. As an example, the air flow delaying unit 53 may comprise a delay valve.

Therefore, when the semiconductor device manufacturing process is initiated, air is supplied simultaneously to the air lines 51, 61 by actuating the solenoid valves 52, 62 at the same time. Accordingly, the dump valve 60 is closed before the final valve 50 is opened. Therefore, the helium spike interlock value will be 0 sccm if the helium feed-through or the filter is plugged. In this case, as with the first embodiment, the process will be stopped immediately.

FIG. 6 shows a third embodiment of the present invention. In the third embodiment, the cooling gas supply apparatus has a final valve 50 and a dump valve 60 disposed in parallel in separate air lines 51, 61. Also, solenoid valves 52, 62 for controlling the supply of air from the main pipe 100 to the final valve 50 and to the dump valve 60, respectively, are provided at the ends of the air lines 51, 61 where the lines are connected to the main pipe 100.

The third embodiment is characterized in that a signal delay device 54 is provided at the power input side of the solenoid valve 52. When power from a common power source is supplied to the solenoid valves 52, 62, the solenoid valve 52 is driven later than the solenoid valve 62 due to the operation of the signal delay device 54. To this end, the signal delay device 54 may be a discrete device comprising a delay circuit, and may be connected to the input of the solenoid valve 52. Alternatively, the signal delay device may comprise a delay circuit formed as part of the driving circuit of the solenoid valve 52. The most representative form of electronic device for such a signal delay device 54 is a flip-flop.

In this embodiment, when power is supplied from the common power supply for use in actuating the solenoid valve 52 and the solenoid valve 62, the solenoid valve 52 is actuated at a point in time later than that at which the solenoid valve 62 is actuated, due to the provision of the signal delay device 54. Accordingly, the solenoid valve 62 first closes the discharge line. Then, the cooling gas is directed through the final valve 50 towards the processing chamber.

At this time, as in the previous embodiments, the helium spike interlock value is 0 sccm if the helium feed-through or the filter is plugged up. Thus, the controller recognizes that the helium spike interlock value is smaller than the predetermined control value, judges there to be a process error, and stops the manufacturing process.

As was described above, the present invention provides a cooling gas supply apparatus in which dump valve 60 is driven earlier than the final valve 50. Thus, when a helium feed-through or a filter disposed in the cooling gas line is clogged with plasma, the controller recognizes this condition as a process error and stops the plasma manufacturing process. Accordingly, the process will not be allowed to proceed without a predetermined amount of the cooling gas being supplied to the processing chamber. Accordingly, the present invention can prevent the manufacturing of inferior wafers or other workpieces.

Finally, although the present invention was described in detail above in connection with the preferred embodiments thereof, the scope of the invention is not so limited. Rather, various changes and modifications of the preferred embodiments, as will become apparent to those of ordinary skill in the art, are seen to be within the true spirit and scope of the invention as defined by the appended claims.

What is claimed is:

1. The combination of a processing chamber, a chuck disposed within said process chamber, and apparatus for supplying cooling gas to a surface of a workpiece disposed on the chuck within the process chamber, wherein said apparatus comprises:
a cooling gas supply line extending into said process chamber, and through which cooling gas is supplied to cool the workpiece disposed on the chuck;
a normally closed final valve disposed in said cooling gas supply line and fluid-operable to open and close said cooling gas supply line so as to control the supplying of cooling gas through said cooling supply line and into the process chamber;
a discharge line connected to said cooling gas supply line downstream of said final valve;
a normally open dump valve disposed in said discharge line and fluid-operable to open and close said discharge line so as to discharge cooling gas, that has been supplied past said final valve, from said cooling supply line;
a main fluid supply pipe through which pressurized fluid flows for use in operating said main valve and said dump valve;
a pair of solenoid valves connected to said main fluid supply pipe so as to constitute branches from said main fluid supply pipe, respectively, and operative to control the flow of fluid through said branches; and
a pair of separate fluid supply lines disposed in parallel as connected to said main pipe via said solenoid valves, respectively, whereby the solenoid valves control the supplying of fluid through the respective air lines, one of said fluid supply lines extending from a respective one of said solenoid valves to said final valve, the other of said fluid supply lines extending from the other of said solenoid valves to said dump valve, and said one of said fluid supply lines being longer than said other of said fluid supply lines such that the final valve will begin to open after the point in time that the dump valve has begun to close when said solenoid valves are actuated simultaneously to allow fluid to flow through said fluid supply lines.

2. The combination of claim 1, wherein the relative lengths of said fluid supply lines are such that said final valve begins to open immediately after said dump valve is closed when said solenoid valves are actuated simultaneously to allow fluid to flow through said fluid supply lines.

3. The combination of a processing chamber, a chuck disposed within said process chamber, and apparatus for supplying cooling gas to a surface of a workpiece disposed on the chuck within the process chamber, wherein said apparatus comprises:
a cooling gas supply line extending into said process chamber, and through which cooling gas is supplied to cool the workpiece disposed on the chuck;
a normally closed final valve disposed in said cooling gas supply line and fluid-operable to open and close said cooling gas supply line so as to control the supplying of cooling gas through said cooling supply line and into the process chamber;
a discharge line connected to said cooling gas supply line downstream of said final valve;
a normally open dump valve disposed in said discharge line and fluid-operable to open and close said discharge line so as to discharge cooling gas, that has been supplied past said final valve, from said cooling supply line;
a main fluid supply pipe through which pressurized fluid flows for use in operating said main valve and said dump valve;
a pair of solenoid valves connected to said main fluid supply pipe so as to constitute branches from said main fluid supply pipe, respectively, and operative to control the flow of fluid through said branches;
a pair of separate fluid supply lines disposed in parallel as connected to said main pipe via said solenoid valves, respectively, whereby the solenoid valves control the supplying of fluid through the respective air lines, one of said fluid supply lines extending from a respective one of said solenoid valves to said final valve, the other of said fluid supply lines extending from the other of said solenoid valves to said dump valve; and
an air flow delaying unit disposed in said one of said fluid supply lines and operative to delay a flow of the fluid through said one of said fluid supply lines such that the final valve will begin to open after the point in time that the dump valve has begun to close when said solenoid valves are actuated simultaneously to allow fluid to flow through said one of the fluid supply lines.

4. The combination of claim 3, wherein said air flow delaying unit is operative to regulate the amount of fluid flowing through said one of the fluid supply lines.

5. The combination of claim 3, wherein said air flow delaying unit is a delay valve.

6. The combination of a processing chamber, a chuck disposed within said process chamber, and apparatus for supplying cooling gas to a surface of a workpiece disposed on the chuck within the process chamber, wherein said apparatus comprises:
a cooling gas supply line extending into said process chamber, and through which cooling gas is supplied to cool the workpiece disposed on the chuck;
a normally closed final valve disposed in said cooling gas supply line and fluid-operable to open and close said cooling gas supply line so as to control the supplying of cooling gas through said cooling supply line and into the process chamber;
a discharge line connected to said cooling gas supply line downstream of said final valve;
a normally open dump valve disposed in said discharge line and fluid-operable to open and close said discharge line so as to discharge cooling gas, that has been supplied past said final valve, from said cooling supply line;
a main fluid supply pipe through which pressurized fluid flows for use in operating said main valve and said dump valve;
a pair of solenoid-actuated valves connected to said main fluid supply pipe so as to constitute branches from said main fluid supply pipe, respectively, and operative to control the flow of fluid through said branches;
a pair of separate fluid supply lines disposed in parallel as connected to said main pipe via said solenoid-actuated valves, respectively, whereby the solenoid-actuated valves control the supplying of fluid through the respective air lines, one of said fluid supply lines extending from a respective one of said solenoid-actuated valves to said final valve, the other of said fluid supply lines extending from the other of said solenoid-actuated valves to said dump valve; and
a signal delay device operatively connected to the solenoid-actuated valve to which said one of said fluid supply lines is connected, said signal delay device being operative to delay the flow of current to the solenoid-actuated valve to which said one of said fluid supply lines is connected relative to the timing at which current flows to the solenoid-actuated valve to which said other of said fluid supply lines is connected such that the final valve will begin to open after the point in time that the dump valve has begun to close when power is supplied from a common power source to the solenoids of said solenoid-actuated valves.

7. The combination of claim 6, wherein said signal delay device of comprises a flip-flop.

8. The combination of a processing chamber, a chuck disposed within said process chamber, and apparatus for supplying cooling gas to a surface of a workpiece disposed on the chuck within the process chamber, wherein said apparatus comprises:
a cooling gas supply line extending into said process chamber, and through which cooling gas is supplied to cool the workpiece disposed on the chuck;
a normally closed final valve disposed in said cooling gas supply line and fluid-operable to open and close said cooling gas supply line so as to control the supplying of cooling gas through said cooling supply line and into the process chamber;
a discharge line connected to said cooling gas supply line downstream of said final valve;
a normally open dump valve disposed in said discharge line and fluid-operable to open and close said discharge line so as to discharge cooling gas, that has been supplied past said final valve, from said cooling supply line;
a main fluid supply pipe through which pressurized fluid flows for use in operating said main valve and said dump valve;
a pair of solenoid-actuated valves connected to said main fluid supply pipe so as to constitute branches from said main fluid supply pipe, respectively, operative to control the flow of fluid through said branches, and connected to said final valve and to said dump valve, respectively, so as to control the supplying of fluid along said branches between said main pipe and said valves; and
delay means for causing the final valve to begin to open after the point in time that the dump valve has begun to close when said solenoid-actuated valves are actuated simultaneously.
